(19) United States
(12) Patent Application Publication
(10) Pub. No.: US 2003/0006064 A1
(43) Pub. Date: Jan. 9, 2003

(54) Circuit board for memory components

(75) Inventors: Martin Gall, Munich (DE); Simon Muff, Hohenkirchen (DE)

Correspondence Address: WITHROW & TERRANOVA, P.L.L.C., P.O. BOX 1287, CARY, NC, 27512, US

(73) Assignee: Infineon Technologies AG, Munich (DE)

(21) Appl. No.: 10/152,496

(22) Filed: May 21, 2002

(30) Foreign Application Priority Data
May 22, 2001 (DE) 101 25 025 . 8

(51) Int. Cl. H05K 1/16

(52) U.S. Cl. 174/260; 361/684

(57) ABSTRACT

The present invention provides a circuit board for at least one memory component which has a housing and electrical contacts on the underside of the housing, the circuit board having a first surface and a second surface, contacts on the first surface of the circuit board which are assigned to the contacts of the at least one memory component, contact balls which connect the contacts of the at least one memory component to the assigned contacts of the circuit board, and conductor tracks having a first end and a second end, which are assigned to the contacts on the first surface of the circuit board and are connected at the first end to said contacts, the conductor tracks extending between their first end and their second end on a surface of the circuit board beyond the periphery of the housing of the at least one memory component.

This, application claims the benefit of German application number 101 25 025.8, filed May 22, 2001, currently pending, the disclosure of which is hereby incorporated by reference in its entirety.

### FIELD OF THE INVENTION

The present invention relates to a circuit board for memory components.

### BACKGROUND OF THE INVENTION

Currently in memory modules which are equipped with memory components, memory modules are used with double-row terminals (DIMM; DIMM=Dual Inline Memory Module). These DIMM modules usually have a register and a phase-locked loop (PLL) for inputting a clock signal into the register and for the delayed outputting (redrive) of the clock signal by means of the phase-locked loop. The timing of the phase-locked loop must be set by measurement, from which the suitable value for the capacitance to be set for the phase-locked loop is obtained. In memory modules, memory components with housings which have a small outline (small outline packages) are usually used, the contact pins being arranged peripherally, i.e. around the periphery, in such memory components and thus being readily accessible for measurements.

If, however, relatively high speeds and data rates are desired, for example, in computer systems and on the main circuit boards in them, the clock frequencies with which the main circuit boards are operated must be increased, which, in housings with externally arranged pins (small outline packages), leads to an increased inductance of the housing of memory components and thus puts the operational capability of the memory components, and the possibility of reliable measurements, at risk.

In order to avoid this problem, dynamic direct access memories DRAM; DRAM=Dynamic Random Access Memory) or the associated passive components, for example phase-locked loops and registers, chip scale housings (chip scale packages) or chip size housings (chip size packages) or CSP housings of the BGA type, which are arranged on the memory modules as, for example, DIMM memory modules which are not buffered or are provided with registers, are used for memory components. In the case of CSP housings of the BGA type the contacts or pins of each housing are located under the housing body and after the housing is installed on a circuit board using a ball grid array (BGA) which connects the contacts of the memory component to the contacts of the circuit board, said contacts or pins are no longer directly accessible for a measurement, for example when the memory module is tested.

A problem in the prior art is therefore that, after the installation of memory components on the circuit board of a memory module with a ball grid array (BGA), it is not possible to measure the signal shapes of the signals of memory components or to synchronize the signals of memory components with respect to one another.

The object of the present invention is consequently to provide a circuit board for memory components and a conductor track structure for a circuit board which permit signal shapes of memory components to be measured and signals of the memory components to be synchronized with respect to one another after the installation on the circuit board.

This object is achieved by means of a circuit board according to claim 1 and a conductor track structure according to claim 10.

### SUMMARY OF THE INVENTION

The circuit board according to the invention and the conductor track design according to the invention have, inter alia, the advantage that in CSP housings of the BGA type for memory components such as, for example, DRAM memory components, it is readily possible to measure signal shapes of the memory component and to synchronize signals in the memory component because, near to the memory components, contact faces are provided which are connected to the concealed actual contacts of the memory components by means of conductor tracks.

Advantageous developments and improvements of the dividing board specified in claim 1 are to be found in the subclaims.

According to one preferred development of the circuit board of the invention, the conductor tracks are arranged on the first surface of the circuit board.

According to a further preferred development of the circuit board of the invention, the conductor tracks are arranged on the second surface of the circuit board.

According to a further preferred development of the circuit board of the present invention, the conductor tracks are connected at their second end by means of vias.

An advantage of this preferred development is that the vias which are provided for rewiring can be used for the purpose of testing memory components with housings of the BGA type.

According to a further preferred development of the circuit board of the present invention, the conductor tracks have contact faces at their second end.

According to a further preferred development of the circuit board of the present invention, the contact balls which are assigned to each memory component are arranged in a ball grid array (BGA).

According to a further preferred development of the circuit board of the present invention, the housing of the memory component has a chip scale housing or chip size housing (CSP housing).

An advantage of this preferred development is that CSP housings permit improved electrical behavior of memory components etc. and of memory modules.

According to a further preferred development of the circuit board of the present invention, the memory components have dynamic direct access memories (DRAM; DRAM=Dynamic Random Access Memory).

According to a further preferred development of the circuit board of the present invention, the circuit board has a plurality of memory components which form a memory module with double-row terminals (DIMM; DIMM=Dual Inline Memory Module).

### BRIEF DESCRIPTION OF THE DRAWING FIGURES

Preferred exemplary embodiments of the present invention are explained in more detail below with reference to the appended drawings, in which:

FIG. 1 shows a plan view and a side view along a line A-A′ of a first preferred exemplary embodiment of the circuit board according to the present invention;

FIG. 2 shows a further plan view of FIG. 1 with components removed from the bases.

In the figures, identical reference numerals designate identical or functionally identical components.

### DETAILED DESCRIPTION OF THE PREFERRED EMBODIMENTS

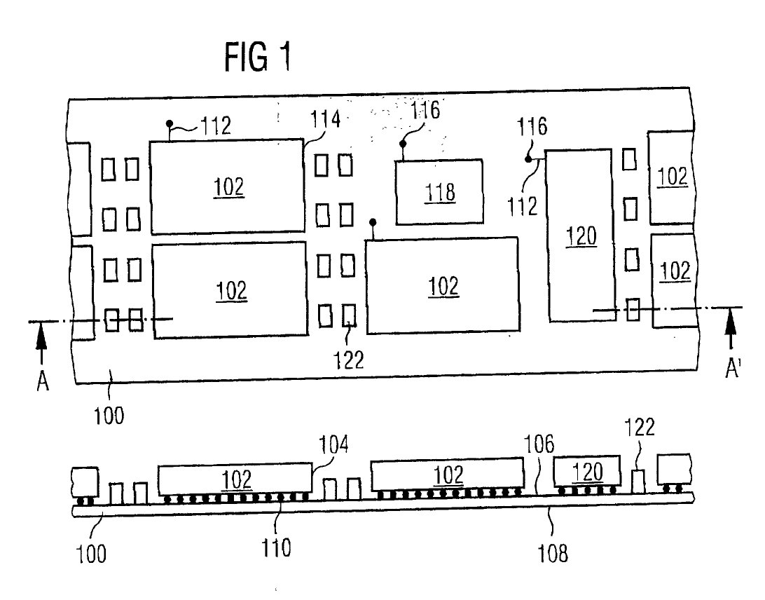

FIG. 1 shows a plan view and a side view along the line A-A′ of a first preferred exemplary embodiment of the circuit board according to the present invention. The circuit board 100 has at least one memory component 102. The memory component 102 is preferably a dynamic direct access memory (DRAM), and a plurality of memory components are preferably arranged on the circuit board 100 to form a memory module, for example a memory module with double-row terminals (DIMM). The memory component has a housing 104 and electrical contacts on the underside of the housing 104. The housing 104 is, for example, a chip scale or chip size (CSP) housing.

The circuit board 100 also has a first surface 106 and a second surface 108. Contacts, preferably contact faces, which are assigned to the contacts of the at least one memory component 102 are arranged on the first surface 106 of the circuit board. The contacts on the circuit board 100 can be connected through from the first surface 106 to the second surface 108 of the circuit board 100 by means of vias. The contacts of the at least one memory component 102 are connected to the assigned contacts on the circuit board 100 via contact balls 110, preferably solder balls, which can have a spherical shape or a similar shape which is suitable for connection. The contact balls 110 are preferably arranged here in a ball grid array (BGA).

The circuit board also has conductor tracks 112 which comprise a first and a second end. The conductor tracks 112 are assigned to the contacts on the first surface 106 of the circuit board 100, and the first end of each conductor track 112 is connected to an assigned contact. The conductor tracks 112, which are assigned to a memory component 102, extend outward between their first end and their second end on a surface, preferably either the first surface 106 or the second surface 108, of the circuit board 100 beyond the outline or the periphery 114 of the housing 104, next to the memory component 102.

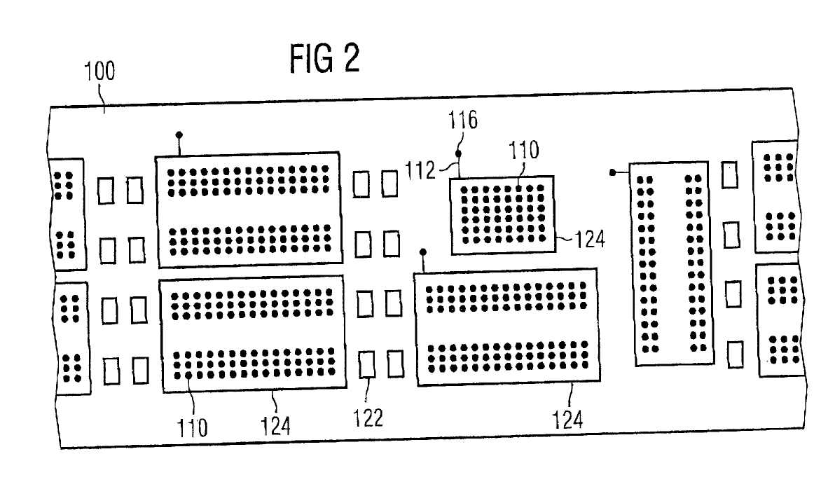

In a first exemplary embodiment, which is shown in FIGS. 1 and 2, the conductor tracks 112 are arranged on the first surface 106 of the circuit board 100. These conductor tracks 112 are connected, underneath the housing 104 of each memory component 102, to, in each case, one contact on the first surface of the circuit board 100, which contact is assigned to a contact of the memory component 102, and conductor tracks 112 extend outward between the memory component 102 and circuit board 100 over the periphery 114 of the housing 104 so that they are accessible on the exposed part of the first surface 106 of the circuit board 100. The conductor tracks 112 are preferably provided at their second end with contact faces or contact pads or test pads with which contact can be made by means of test probes or tips of contact elements.

In a second preferred exemplary embodiment of the circuit board according to the present invention, the conductor tracks 112 are arranged on the second surface 108 of the circuit board 100. The contacts on the circuit board 100 are, for this purpose, preferably connected through from the first surface 106 to the second surface 108 of the circuit board 100 by means of vias in order to be connected to the second end of the conductor tracks, or the memory elements have contact pins which extend from the first surface 106 to the second surface 108 of the circuit board 100. The conductor track 112 are preferably connected at their second end by means of vias which bring about a connection between the second surface 108 and the first surface 106 of the circuit board 100 in order in turn to produce a through-contact from the rear side or the second surface 108 of the circuit board 100 to the front side or the first surface 106 of the circuit board. Such vias can additionally be provided in the circuit board 100 or are already provided on the circuit board 100 for other purposes, for example rewiring. In the vias, the conductor tracks 112 preferably have contact faces 116 to which test probes or the tips of contact elements can be connected.

In a third preferred exemplary embodiment of the circuit board according to the present invention, the conductor tracks 112 are arranged both on the first surface 106 and the second surface 106 of the circuit board 100.

FIG. 1 also shows a phase-locked loop 118 and a register 120 which receive a clock signal for, for example, a memory module and output it with a delay in order to actuate the memory elements 102 with suitable timing. Conductor tracks 112 with contact faces 116 are also extended to the sides of both the phase-locked loop 118 and the register 120 in order to be able to test these components. In addition, passive elements, for example capacitors 122 etc. which serve to wire the memory components 102 are provided on the circuit board 100.

FIG. 2 shows a further plan view of the first preferred exemplary embodiment of the circuit board in FIG. 1, the memory components 102, the phase-locked loop 118 and the register 120 being removed from their assigned bases 124. FIG. 2 clearly shows the contact balls 110 which are preferably arranged here in ball grid arrays (BGA) or rows or blocks of balls which are connected to contact faces 116 via the conductor tracks 112.

A preferred exemplary embodiment of a conductor track structure according to the invention for a circuit board 100, which is provided for at least one memory component 102, is described below with reference to FIG. 1. The memory component 102 has, as described above, a housing 104 and electrical contacts on the underside of the housing 104. The circuit board 100 has a first surface 106 and a second surface 108, contacts on the first surface 106 of the circuit board 100, which are assigned to the contacts of the at least one memory component 102, and contact balls 110 which connect the contacts of the at least one memory component 102 to the assigned contacts on the circuit board 100.

The conductor track structure has conductor tracks 112 which each comprise a first end and a second end. The conductor tracks 112 are assigned to the contacts on the first surface 106 of the circuit board 100 and are connected to said contacts at the first end of the conductor track 112. The conductor tracks 112 extend between the first end and the second end thereof on a surface, preferably either the first or the second surface 106, 108 of the circuit board 100 beyond the periphery 114 of the housing 104, i.e. either underneath the underside of the housing 104 and on the first surface 106 of the circuit board 100 beyond the periphery 114 of the housing 104 of the memory component, or on the second surface 108 of the circuit board 100 from through-going contacts of the memory component 102 to vias outside the periphery 114 of the memory component 102 and then to the first surface 106 of the circuit board 100. The conductor tracks 112 also preferably have at their second end a contact face 106 for test probes and the tips of contact elements. The arrangement of the memory components 102, of contact balls 110 etc. is similar or identical to the exemplary embodiments of the circuit board which are described above, and is therefore not explained in more detail.

One advantage of the present invention is that it permits very simple testing of memory components with CSP housings of the BGA type which are installed on circuit boards without putting at risk the functioning of the memory components, and nevertheless permitting a high packing density.

Although the present invention is described above with reference to preferred exemplary embodiments, it is not restricted thereto, but instead can be modified in various ways.

List of reference numerals:

| | |
|---|---|
| 100 | Circuit board |
| 102 | Memory component |
| 104 | Housing |
| 106 | First surface of 100 |
| 108 | Second surface of 100 |
| 110 | Contact balls |
| 112 | Conductor tracks |
| 114 | Periphery of the housing 104 |
| 116 | Contact faces |
| 118 | Phase locked loop |
| 120 | Register |
| 122 | Passive elements |
| 124 | Bases of 102, 118, 120 |

1. Circuit board for at least one memory component which has a housing and electrical contacts on the underside of the housing, having the following features:
a first surface and a second surface;
contacts on the first surface of the circuit board which are assigned to the contacts of the at least one memory component;
contact balls which connect the contacts of the at least one memory component to the assigned contacts of the circuit board; and
conductor tracks having a first end and a second end, which are assigned to the contacts on the first surface of the circuit board and are connected at the first end to said contacts, the conductor tracks extending between their first end and their second end on a surface of the circuit board beyond the periphery of the housing of the at least one memory component.

2. Circuit board according to claim 1, in which the conductor tracks are arranged on the first surface of the circuit board.

3. Circuit board according to claim 1, in which the conductor tracks are arranged on the second surface of the circuit board.

4. Circuit board according to claim 1, in which the conductor tracks are connected at their second end by means of vias.

5. Circuit board according to claim 1, in which the conductor tracks have contact faces at their second end.

6. Circuit board according to claim 1, in which the contact balls which are assigned to each memory component are arranged in a ball grid array.

7. Circuit board according to claim 1, in which the housing of the memory component has a chip scale or chip size housing.

8. Circuit board according to claim 1, in which the memory components have dynamic direct access memories.

9. Circuit board according to claim 1, in which the circuit board has a plurality of memory components which form a memory module with double-row terminals.

10. Conductor track structure for a circuit board, which is provided for at least one memory component which has a housing and electrical contacts on the underside of the housing, and which has a first surface and a second surface, contacts on the first surface of the circuit board, which are assigned to the contacts of the at least one memory component, and contact balls which connect the contacts of the at least one memory component to the assigned contacts on the circuit board, the conductor track structure having the following feature:
conductor tracks having a first end and a second end which are assigned to the contacts on the first surface of the circuit board and are connected at the first end to said contacts,
conductor tracks extending between their first end and their second end on a surface of the circuit board beyond the circumference of the housing of the at least one memory component.

11. Conductor track structure according to claim 10, in which the conductor tracks are arranged on the first surface of the circuit board.

12. Conductor track structure according to claim 10, in which the conductor tracks are arranged on the second surface of the circuit board.

13. Conductor track structure according to claim 10, in which the conductor tracks are connected at their second end by means of vias.

14. Conductor track structure according to claim 10, in which the conductor tracks have contact faces at their second end.

15. Conductor track structure according to claim 10, in which the contact balls which are assigned to each memory element are arranged in a ball grid array.

16. Circuit board according to claim 10, in which the housing of the memory element has a chip scale or chip size housing.

17. Conductor track structure according to claim 10, in which the memory components have dynamic direct access memories.

18. Conductor track structure according to claim 10, in which the circuit board has a plurality of memory elements which form a memory module with double-row terminals.
